(19) United States
(12) Patent Application Publication
(10) Pub. No.: US 2009/0251229 A1
(43) Pub. Date: Oct. 8, 2009

(54) SELF-OSCILLATING MODULATOR WITH IMPROVED SYNCHRONISATION AND PWM CYCLE CONSTRAINTS

(75) Inventors: Lars Arknaes-Pedersen, Viby (DK); Kim Rishoj Pedersen, Ega (DK)

Correspondence Address: CANTOR COLBURN, LLP, 20 Church Street, 22nd Floor, Hartford, CT, 06103, US

(73) Assignee: TC GROUP, Risskov (DK)

(21) Appl. No.: 12/373,360

(22) PCT Filed: Jul. 11, 2007
(86) PCT No.: PCT/DK07/50091

§ 371 Date: Jan. 12, 2009

(30) Foreign Application Priority Data
Jul. 11, 2006 (DK) PA 2006 00957

(51) Int. Cl. H03K 7/08

(52) U.S. Cl. 332/109

(57) ABSTRACT

The present invention relates to a self-oscillating modulator (2) comprising a PWM cycle constrainer (21). The present invention further relates to a method of stabilising the switch frequency of a self-oscillating modulator operating on a high level input signal, whereby at least one PWM cycle constraint representative signal (26, 32, 33) is applied to a pulse width modulated signal (18) within said self-oscillating modulator (2). The present invention further relates to a method of avoiding pulses narrower than a predetermined minimum pulse width or wider than a predetermined maximum pulse width in a self-oscillating modulator (2) operating on a high level input signal, whereby at least one PWM cycle constraint representative signal (26, 32, 33) is applied to a pulse width modulated signal (18) within said self-oscillating modulator. The present invention further relates to a method of providing at least one PWM cycle constraint representative signal (26, 32, 33) for use in a self-oscillating modulator, whereby said PWM cycle constraint representative signal is established by the steps of: providing a periodic signal (17, 25, 31) by means of a reference signal generator (22), providing a square wave signal (31) on the basis of, and in synchrony with, said periodic signal (17, 25), and providing said PWM cycle constraint representative signal (26, 32, 33) on the basis of, and in synchrony with, said square wave signal (31).

### FIELD OF THE INVENTION

The present invention relates to self-oscillating amplifiers or modulators.

### BACKGROUND OF THE INVENTION

Self-oscillating pulse width modulation (PWM) amplifiers, e.g. for audio applications, are generally recognised as advantageous over common PWM amplifiers that modulates the input signal by means of a triangle or saw tooth reference signal, as they provide for a significant better error attenuation, e.g. easily more than 20 dB better error attenuation at 20 kHz.

Known self-oscillating PWM amplifiers do, however, also suffer from a disadvantage, as their switch frequency fluctuates with the level of the input signal. The switch frequency decreases with increasing input level, and may typically be halved at input signals at 80% of maximum level. Among other things, this problem complicates operating more amplifiers simultaneously, e.g. in a multi-channel application, due to cross-talk, and moreover, it also increases problems with cross-talk to other system components such as, e.g., converters, phase-locked-loops, tuners, etc.

In the past, this problem has been addressed by injecting a relatively small, periodic, typically triangular, reference signal into the loop, whereby the oscillation tends to lock to the frequency of the reference signal, within certain limits. The amplitude of the reference signal compared to the maximum input signal level determines how firmly the switch frequency locks, and a triangular reference signal of, e.g. 15% of the maximum input signal level, stabilises the switch frequency significantly for input signals of up to 70%-80% of maximum, whereas it is still not able to maintain the switch frequency for larger input signals. Reference signals of larger amplitudes may be able to reduce the fluctuation for larger input levels, but will also reduce the advantages of self-oscillation significantly, and result in an overall performance corresponding to non-self-oscillating, reference signal driven PWM amplifiers.

A further problem for known self-oscillating PWM amplifiers is that very large input signals close to 100% maximum level may cause PWM pulses that do not satisfy the minimum pulse widths required by the power output stage in order to avoid distortion, and ensure that a pulse is present for each switch period. As a self-oscillating loop is driven by the pulses inherent in the signal, the oscillation stops when the duty cycle becomes 0% or 100%, as no level shifts occur at such duty cycles. Because of the minimum pulse width requirements of the output stage, caused by the rise- and fall-time of the power switches, which are typically somewhat slower than the low-voltage processing means establishing the pulses, the problem with missing level shifts may in fact occur also for duty cycles close to 0% or 100% of maximum level, e.g. for duty cycles below 4% or above 96%, which may correspond to, e.g., an input signal level above 92% of maximum.

It is an object of the present invention to provide a self-oscillating modulator that features improved switch frequency locking for large input signals.

It is an object of the present invention to provide a self-oscillating modulator that ensures observance of the minimum pulse width requirements.

It is an object of the present invention to provide a self-oscillating modulator or amplifier with improved handling of large input signals, e.g. less cross-talk and less distortion.

### SUMMARY OF THE INVENTION

The invention relates to a self-oscillating modulator 2 comprising a PWM cycle constrainer 21.

According to the present invention, an advantageous self-oscillating modulator, e.g. an audio amplifier, may be provided, which features improved switch frequency locking also for input utility signals with high levels, i.e. frequency locking in an increased dynamic range compared to known frequency locking methods described above.

Moreover, according to the present invention, an advantageous self-oscillating modulator may be provided, which ensures compliance with the minimum duty cycle requirements typically introduced by power output stages with slower switching capabilities than offered by the modulation circuitry or processing means.

In a preferred embodiment, both objects are fulfilled and hence, a self-oscillating modulator that ensures a stable and synchronised oscillation and thereby, among other things, reduced cross-talk effects, and at the same time guarantees a minimum pulse width to be realised by the output stage, and thereby reduces distortion, is provided according to the invention.

When said PWM cycle constrainer 21 is arranged for establishing switch frequency synchronisation in an increased dynamic range of said self-oscillating modulator, an advantageous embodiment of the present invention has been obtained.

According to the present invention, it is ensured that the pulse width modulated signal supplied to a switching power output stage comprises at least one pulse or level shift in each PWM period, i.e. each period of the switch frequency of the self-oscillating modulator, even when the input utility signal has a high level compared to its maximum possible level. The guarantee of at least one shift in each period causes the switch frequency to stabilise, and thereby avoids frequency fluctuation and momentary oscillation pauses, which again avoids or reduces cross-talk problems.

When said PWM cycle constrainer 21 is arranged for ensuring that a pulse width modulated signal 18 of said self-oscillating modulator 2 comprises a pulse of at least a predetermined minimum width in each switch period, an advantageous embodiment of the present invention has been obtained.

According to the present invention, it is ensured that the pulse width modulated signal supplied to a switching power output stage never comprises pulses narrower than a predetermined pulse width. Thereby distortion due to the power switches not being able to realise very narrow pulses because of their relative long rise- and fall-times is avoided.

When said PWM cycle constrainer 21 is arranged for ensuring that a pulse width modulated signal 18 of said self-oscillating modulator 2 comprises a pulse of less than or equal to a predetermined maximum width in each switch period, an advantageous embodiment of the present invention has been obtained.

When said PWM cycle constrainer 21 is arranged for ensuring that said pulse in each switch period is in synchrony with the oscillation of said self-oscillating modulator, an advantageous embodiment of the present invention has been obtained.

When said PWM cycle constrainer 21 comprises a PWM cycle constraint generator 23 arranged for establishing at least one PWM cycle constraint representative signal 26; 32, 33, an advantageous embodiment of the present invention has been obtained.

When said PWM cycle constraint representative signal 26; 32, 33 is applied to a pulse width modulated signal 18 within said self-oscillating modulator 2 by means of a limit pattern logic 24.

When said PWM cycle constraint representative signal 26; 32, 33 is a pulse width modulated signal, an advantageous embodiment of the present invention has been obtained.

When said PWM cycle constraint representative signal 26; 32, 33 comprises a maximum duty cycle representative signal 32 and a minimum duty cycle representative signal 33, an advantageous embodiment of the present invention has been obtained.

When said maximum duty cycle signal 32 comprises at least one pulse per switch period of said self-oscillating modulator 2, and wherein the duty cycle of said maximum duty cycle signal 32 is in the range of 90% to 99%, preferably substantially 96%, an advantageous embodiment of the present invention has been obtained.

A predetermined minimum pulse width that suits a typical switching power output stage, may, e.g., be 100 ns. In a self-oscillating amplifier with a switch frequency of, e.g., 400 kHz, this minimum pulse width corresponds to 4% or 96% duty cycle, as one switch period last for 2500 ns. It is noted, however, that the principles of the present invention applies to any self-oscillating modulators running at any suitable switch frequencies, and supplies any suitable power output stages or other kinds of subsequent processing blocks, having any minimum pulse width requirements. In such alternative embodiments, the maximum and minimum duty cycle signals should be designed according to the principles described herein, and on the basis of the desired or needed switch frequency and the actual minimum pulse width requirements.

When said duty cycle of said maximum duty cycle signal 32 corresponds to one full switch period of said self-oscillating modulator 2 subtracted by an amount of time in the range of 50 ns to 200 ns, preferably 100 ns, an advantageous embodiment of the present invention has been obtained.

When said minimum duty cycle signal 33 comprises at least one pulse per switch period of said self-oscillating modulator 2, and wherein the duty cycle of said minimum duty cycle signal 33 is in the range of 1% to 10%, preferably substantially 4%, an advantageous embodiment of the present invention has been obtained.

When said pulse length of said minimum duty cycle signal 33 is in the range of 50 ns to 200 ns, preferably 100 ns, an advantageous embodiment of the present invention has been obtained.

When the low part of said pulse per switch period of said maximum duty cycle signal 32 is located in the beginning of each switch period, an advantageous embodiment of the present invention has been obtained.

When the low part of said pulse per switch period of said maximum duty cycle signal 32 is located in the end of each switch period, an advantageous embodiment of the present invention has been obtained.

When the low part of said pulse per switch period of said maximum duty cycle signal 32 is located so that the middle in terms of time of said low part is located substantially at the shift between two switch periods, an advantageous embodiment of the present invention has been obtained.

When the high part of said pulse per switch period of said minimum duty cycle signal 33 is located so that it starts at the middle of each switch period, an advantageous embodiment of the present invention has been obtained.

When the high part of said pulse per switch period of said minimum duty cycle signal 33 is located so that it ends at the middle of each switch period, an advantageous embodiment of the present invention has been obtained.

When the high part of said pulse per switch period of said minimum duty cycle signal 33 is located so that the middle in terms of time of said high part is located substantially at the middle of each switch period, an advantageous embodiment of the present invention has been obtained.

When said locating said pulses of said PWM cycle constraint representative signal 26; 32, 33 is controlled at least partly by a delay in a feedback path of said PWM cycle constraint generator 23, an advantageous embodiment of the present invention has been obtained.

When said limit pattern logic 24 applies said PWM cycle constraint representative signal 26; 32, 33 to said pulse width modulated signal 18 by means of logic operations, an advantageous embodiment of the present invention has been obtained.

When said logic operations comprise applying said maximum duty cycle signal 32 to said pulse width modulated signal 18 by means of an AND operation, and applying said minimum duty cycle signal 33 to said pulse width modulated signal 18 by means of an OR operation, an advantageous embodiment of the present invention has been obtained.

When said PWM cycle constraint generator 23 establishes said PWM cycle constraint signal 26; 32, 33 on the basis of a periodic signal 17; 25; 31, an advantageous embodiment of the present invention has been obtained.

When said periodic signal 17; 25; 31 is in synchrony with the oscillation of said self-oscillating modulator 2, an advantageous embodiment of the present invention has been obtained.

When said periodic signal 17; 25; 31 is a triangle signal, a sawtooth signal, a square wave signal or another signal having a distinct amplitude-time relationship, an advantageous embodiment of the present invention has been obtained.

When said PWM cycle constraint generator 23 establishes said PWM cycle constraint representative signal 26; 32, 33 on the basis of a square wave signal 31 established on the basis of said periodic signal 17, an advantageous embodiment of the present invention has been obtained.

When a synchronization signal 17 is further added to the input signal 3 of said self-oscillating modulator 2, or applied within the loop of the self-oscillating modulator, an advantageous embodiment of the present invention has been obtained.

When said synchronization signal 17 is applied within the loop of the self-oscillating modulator 2 by providing it as reference signal to a modulator 12 of said self-oscillating modulator 2, an advantageous embodiment of the present invention has been obtained.

When said synchronization signal 17 comprises a representation of said periodic signal 17, an advantageous embodiment of the present invention has been obtained.

When said periodic signal 17 is established by means of a self-oscillating loop 22, an advantageous embodiment of the present invention has been obtained.

The self-oscillating loop 22 is also referred to as periodic signal generator 22 or reference signal generator 22 elsewhere in this application.

When said periodic signal 17 is variable, and is controlled at least partly on the basis of the level of said input signal 3 of said self-oscillating modulator 2, an advantageous embodiment of the present invention has been obtained.

When said self-oscillating modulator 2 comprises a controller 11, an advantageous embodiment of the present invention has been obtained.

When said controller 11 comprises a loop filter arranged for at least partly controlling the oscillation of said self-oscillating modulator 2, an advantageous embodiment of the present invention has been obtained.

When said controller 11 comprises at least one integrator, an advantageous embodiment of the present invention has been obtained.

When said self-oscillating modulator 2 comprises a power output stage 13, an advantageous embodiment of the present invention has been obtained.

When said self-oscillating modulator 2 comprises an output filter 14, an advantageous embodiment of the present invention has been obtained.

When said self-oscillating modulator 2 comprises a feedback path 16 from the output of said power output stage 13 to said controller 11, an advantageous embodiment of the present invention has been obtained.

When said self-oscillating modulator 2 comprises a feedback path from the output of said output filter 14 to said controller 11, an advantageous embodiment of the present invention has been obtained.

When said self-oscillating modulator is arranged for establishing a pulse width modulated signal 18 on the basis of an input signal 3, and wherein said self-oscillating modulator comprises
a controller 11,
a modulator 12,
at least one feedback path 16,
a PWM cycle constraint generator 23, and
limit pattern logic 24,
   wherein said PWM cycle constraint generator 23 is arranged for establishing PWM cycle constraint representative signals 26; 32, 33, and wherein said limit pattern logic 24 is arranged for applying said PWM cycle constraint representative signals 26; 32, 33 to said pulse width modulated signal 18, thereby establishing a PWM cycle limited pulse width modulated signal 27, an advantageous embodiment of the present invention has been obtained.

When said self-oscillating modulator comprises a power output stage 13, an advantageous embodiment of the present invention has been obtained.

When said self-oscillating modulator further comprises a reference signal generator 22 arranged for establishing a periodic reference signal 17; 25; 31, an advantageous embodiment of the present invention has been obtained.

When said PWM cycle constraint representative signals 26; 32, 33 are in synchronization with the switch frequency of said self-oscillating modulator 2, an advantageous embodiment of the present invention has been obtained.

The present invention further relates to a method of stabilising the switch frequency of a self-oscillating modulator operating on a high level input signal, whereby at least one PWM cycle constraint representative signal 26; 32, 33 is applied to a pulse width modulated signal 18 within said self-oscillating modulator 2.

When said application of said PWM cycle constraint representative signal 26; 32, 33 to said pulse width modulated signal 18 ensures that said pulse width modulated signal comprises at least one pulse for each switch period, an advantageous embodiment of the present invention has been obtained.

When said at least one PWM cycle constraint representative signal 26; 32, 33 comprises a maximum duty cycle signal 32 that is applied to said pulse width modulated signal 18 by means of an AND operation, and a minimum duty cycle signal 33 that is applied to said pulse width modulated signal 18 by means of an OR operation, an advantageous embodiment of the present invention has been obtained.

When said self-oscillating modulator 2 comprises a self-oscillating modulator according to any of the above described, an advantageous embodiment of the present invention has been obtained.

The present invention further relates to a method of avoiding pulses narrower than a predetermined minimum pulse width or wider than a predetermined maximum pulse width in a self-oscillating modulator 2 operating on a high level input signal, whereby at least one PWM cycle constraint representative signal 26; 32, 33 is applied to a pulse width modulated signal 18 within said self-oscillating modulator.

When said at least one PWM cycle constraint representative signal 26; 32, 33 comprises a maximum duty cycle signal 32 that is applied to said pulse width modulated signal 18 by means of an AND operation, and a minimum duty cycle signal 33 that is applied to said pulse width modulated signal 18 by means of an OR operation, an advantageous embodiment of the present invention has been obtained.

When said maximum duty cycle signal 32 for each switch period of said self-oscillating modulator 2 comprises a low part that is wider than or equal to said predetermined minimum pulse width, and whereby said minimum duty cycle signal 33 for each switch period of said self-oscillating modulator 2 comprises a high part that is wider than or equal to said predetermined minimum pulse width, an advantageous embodiment of the present invention has been obtained.

When said self-oscillating modulator 2 comprises a self-oscillating modulator according to any of the above-described, an advantageous embodiment of the present invention has been obtained.

The present invention further relates to a method of providing at least one PWM cycle constraint representative signal 26; 32, 33 for use in a self-oscillating modulator, whereby said PWM cycle constraint representative signal is established by the steps of:
providing a periodic signal 17; 25; 31 by means of a reference signal generator 22,
providing a square wave signal 31 on the basis of, and in synchrony with, said periodic signal 17; 25, and
providing said PWM cycle constraint representative signal 26; 32, 33 on the basis of, and in synchrony with, said square wave signal 31.

When said reference signal generator 22 comprises a self-oscillating loop with a hysteresis comparator, an advantageous embodiment of the present invention has been obtained.

When said hysteresis comparator has its reference input coupled to ground, an advantageous embodiment of the present invention has been obtained.

When said hysteresis comparator has its reference input coupled to a synchronization signal source, an advantageous embodiment of the present invention has been obtained.

When said providing said PWM cycle constraint representative signal 26; 32, 33 comprises providing a maximum duty cycle signal 32 which for each period of said periodic signal 17; 25; 31 comprises a low part that is wider than or equal to a predetermined minimum pulse width, and further providing a minimum duty cycle signal 33 which for each period of said periodic signal 17; 25; 31 comprises a high part that is wider than or equal to a predetermined minimum pulse width, an advantageous embodiment of the present invention has been obtained.

When said PWM cycle constraint representative signal 26; 32, 33 is used in a self-oscillating modulator 2 according to any of the above-described, an advantageous embodiment of the present invention has been obtained.

### THE DRAWINGS

The invention will in the following be described with reference to the drawings where

FIG. 1 illustrates a prior art self-oscillating modulator,

FIG. 2 illustrates an embodiment of the present invention,

FIG. 3 illustrates a further embodiment of the present invention,

FIG. 4 illustrates a further embodiment of the present invention,

FIG. 5 illustrates signal established by an embodiment of the present invention, and

FIG. 6 to 8 illustrate spectra generated by self-oscillating modulators.

### DETAILED DESCRIPTION

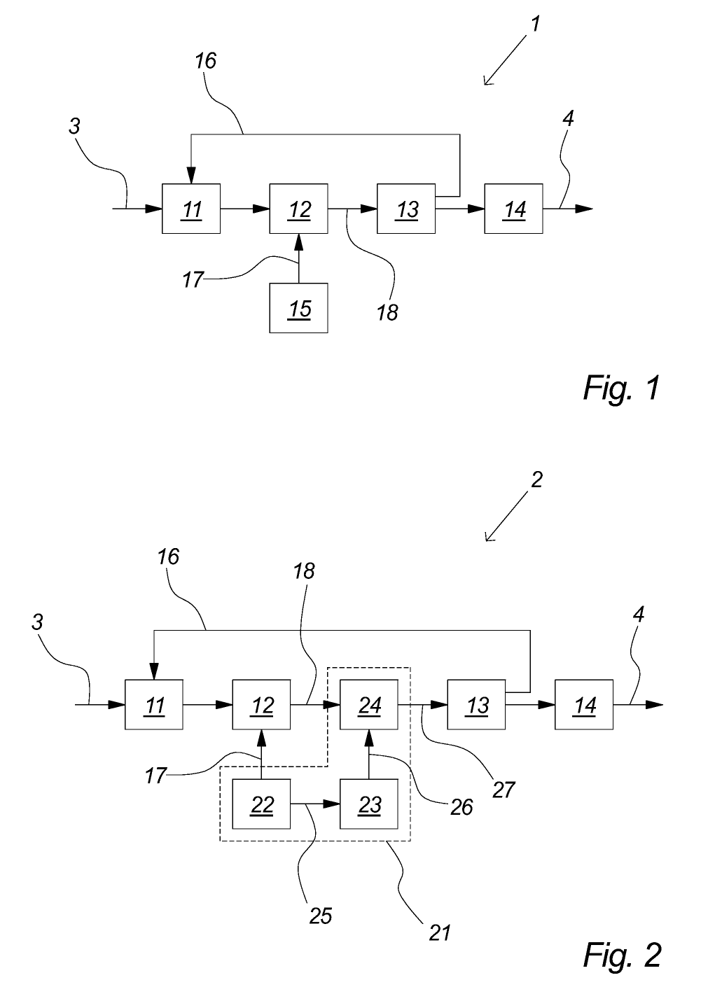

FIG. 1 illustrates a self-oscillating amplifier 1 wherein the problem of fluctuating switch frequency has been reduced by the known method of adding a small-signal periodic reference signal to the signal being amplified. It comprises a controller 11, comprising a suitable loop filter, preferably a linear low pass filter provided by an integrator, which provides suitable oscillation conditions in the loop. The controller 11 receives an input signal 3, e.g. an analog or digital audio signal, and its output is coupled to a modulator 12, comprising a suitable non-linear device, e.g. a comparator, which establishes a pulse width modulated (PWM) signal 18 from the output of the controller 11. The pulse width modulated signal 18 is amplified by a an output stage 13, comprising a suitable switching power stage, comprising suitable power switches, e.g. power FET's, controlled by the pulse width modulated signal 18. The output of the output stage 13 is preferably smoothed, i.e. decoded, by an output filter 14, whereby an amplified output signal 4 is established, representing the input signal 3. A feedback path 16 is provided for facilitating self oscillation.

The theory and principles behind self-oscillating modulators and amplifiers, as well as examples of embodiments suitable for use with the present invention, are described in more detail in the prior art, for example in the published, international patent applications WO 2005/002050 A1, WO 2005/029707 A1 and WO 2005/029708 A1, hereby incorporated by reference.

Instead of coupling the reference input of the modulator 12 to ground or a DC value as in a simple, self-oscillating amplifier, a periodic signal generator 15 is provided for establishing a periodic signal 17 that is coupled to the reference input of the comparator of the modulator 12. The periodic signal may, e.g., have a level of 15% of maximum input signal level, and should have a frequency corresponding to the switch frequency of the self-oscillating modulator.

As described above, a self-oscillating amplifier as shown in FIG. 1 suffers from several problems, among others from not being able to stabilise the switch frequency for high input signal levels and from not being able to prevent the pulse width modulated signal 18 from comprising pulses so narrow that they are impossible for the output stage 13 to realise.

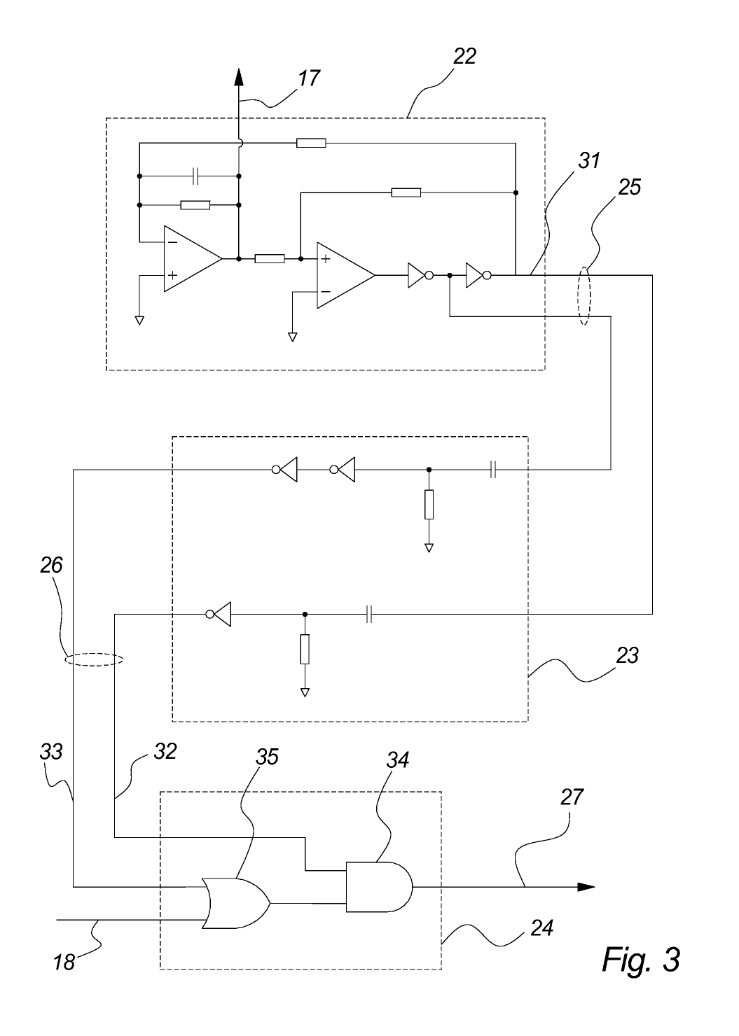

FIG. 2 illustrates an embodiment of the present invention. It comprises a self-oscillating modulator 2 comprising several of the components described above regarding FIG. 1. In addition to those, the embodiment of FIG. 2 comprises a PWM cycle constrainer 21 for solving the two problems mentioned above regarding FIG. 1. The PWM cycle constrainer comprises a periodic signal generator 22 which generates periodic signals 17 and 25, which in a preferred embodiment are synchronised to each other, but may be characterised differently, or at least be of different amplitudes. In a preferred embodiment, the periodic signal 17 is a triangle signal, whereas the signal 25 is a square wave signal of the same frequency as the triangle signal 17. The periodic signal 25 is fed to a PWM cycle constraint generator 23, which establishes at least one PWM cycle constraint representative signal 26 on the basis of the periodic signal 25. The PWM cycle constraint representative signal 26 is fed to a limit pattern logic 24, which applies the PWM cycle constraint representative signal 26 to the pulse width modulated signal 18, and thereby establishes a duty cycle limited PWM signal 27. In addition, the periodic signal 17 may be used for reference input to the modulator 12 or may, in alternative embodiments, be added to the input signal 3, or to the loop signal anywhere in the self-oscillating loop.

The principles behind partially controlling the switch frequency by means of a periodic signal 17, preferably a triangle signal, and different examples of how and where to inject such a signal into the self-oscillating loop, as well as examples of signal types, may, e.g., be found in the published, international patent applications WO 2005/029707 A1, WO 2005/029708 A1, WO 2005/036734 A1 (in particular the parts about the compensation means) and WO 2005/036735 A1 (in particular the parts about the compensation means), hereby incorporated by reference.

In an alternative embodiment, the periodic signal generator 22 is substituted for an external periodic signal generator or source, or it is controlled by an externally generated signal, e.g. a clock signal established elsewhere in the system. In such embodiments the externally provided periodic signal may be used directly for periodic signals 17 and/or 25, or the periodic signal generator 22 may comprise circuitry for deriving suitable periodic signals 17 and/or 25 from the externally provided signal.

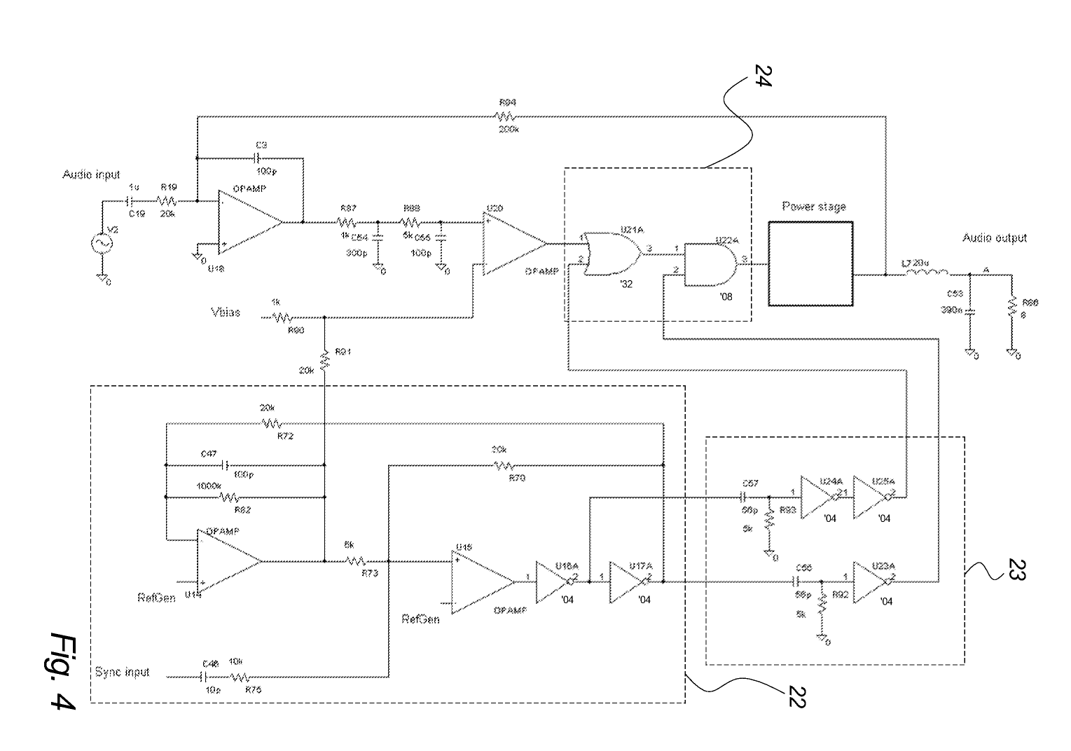

FIG. 3 illustrates a PWM cycle constrainer 21 according to a preferred embodiment of the present invention in more detail. It comprises a periodic signal generator 22, which comprises a hysteresis self-oscillating loop comprising an integrator and a comparator with positive feedback. A couple of inverters provides for steep rise and fall times of the periodic signal 25. The output of the integrator is a triangle signal, and is in a preferred embodiment used for periodic signal 17. FIG. 3 further comprises a PWM cycle constraint generator 23, which receives the periodic signal 25, and on the basis thereof, and in a preferred embodiment, by means of inverters and differentiators, establishes a PWM cycle constraint representative signal 26, which in a preferred embodiment comprises two signal, a maximum duty cycle signal 32 and a minimum duty cycle signal 33. Finally, FIG. 3 illustrates a preferred embodiment of a limit pattern logic 24. The minimum duty cycle signal 33 is applied to the pulse width modulated signal 18 established by the modulator 12 in FIG. 2, by means of an OR-operation 35. The maximum duty cycle signal 32 is applied to the pulse width modulated signal 18 by means of an AND-operation 34 on the output of the OR-gate. The output of the AND-gate 34 is thus the duty cycle limited PWM signal 27 indicated in FIG. 2.

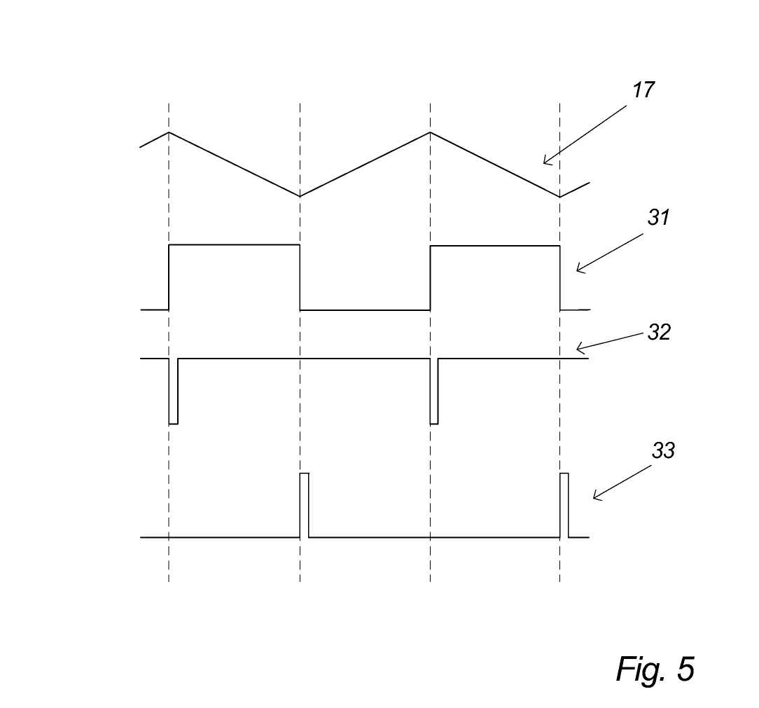

FIG. 4 illustrates a preferred embodiment of the present invention.

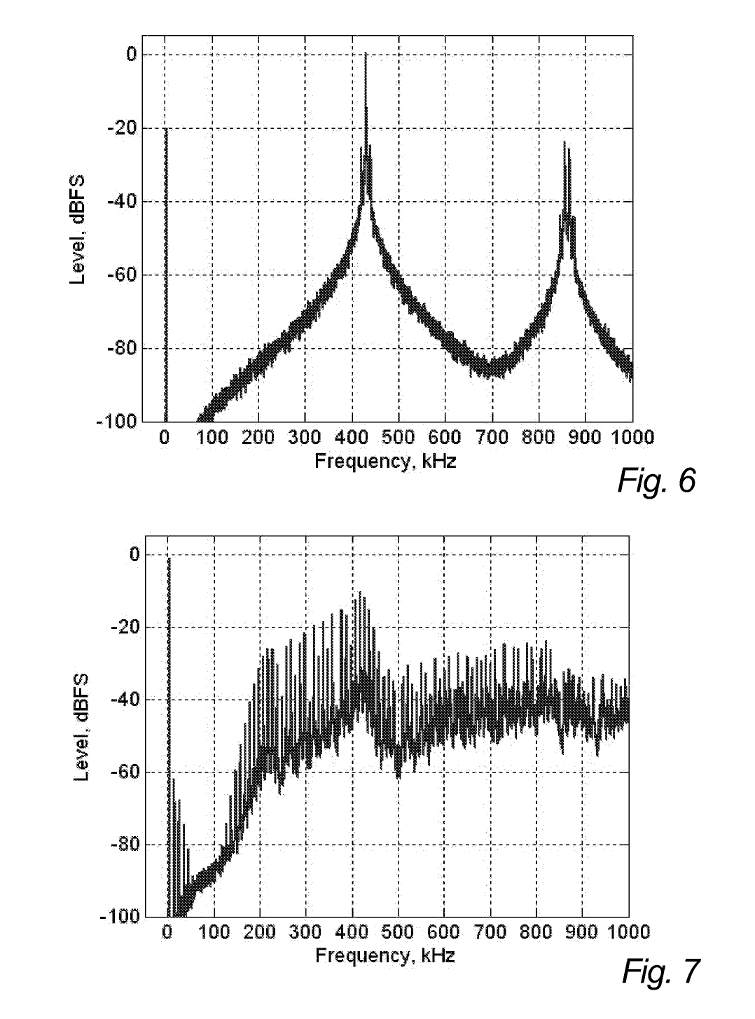

FIG. 5 illustrates preferred waveforms of the key signals of a PWM cycle constrainer according to a preferred embodiment of the present invention. The first wave form 17 is the preferably triangular periodic signal 17 indicated in FIGS. 1, 2 and 3, which is used for stabilising the switch frequency of the self-oscillating amplifier when the input signal level is relatively small. The frequency of the periodic signal 17 corresponds to the desired switch frequency of the self-oscillating loop.

The second wave form is a periodic signal 31 indicated in FIG. 3, and is in the embodiment of FIG. 3, one of two inverted, but otherwise identical, square wave signals comprised by periodic signal 25. The square wave signal 31 corresponds to the triangle signal 17 in that it has the same frequency, same duty cycle and is in phase with the triangle signal.

The third wave form 32 is the maximum duty cycle signal 32 of FIG. 3, and part of the PWM cycle constraint representative signal 26 of FIG. 2. It is established from the square wave signal 31 by means of a differentiator and an inverter, and is thereby low in a short time when the square wave signal shifts to high, but returns after a short time to high, where it stays for the rest of the period. The length of the low part of the pulse may be controlled by the differentiator used to establish it, and should correspond to the minimum pulse width that the output stage of the amplifier is able to realise without acceptable distortion. Such time may, e.g., be 100 ns, and in an embodiment where the switch frequency is 400 kHz, the low pulse is thus 4% of the time, and the duty cycle of the maximum duty cycle signal 32 is thus 96%. This represents the maximum pulse length realisable by the output stage, when a low pulse has to be made in each period in order to facilitate switch frequency stabilisation.

The fourth wave form 33 is the minimum duty cycle signal 33 of FIG. 3, and part of the PWM cycle constraint representative signal 26 of FIG. 2. It is established from an inverted version of the square wave signal 31 by means of a differentiator and two inverters, and is thereby high in a short time when the square wave signal shifts to high, i.e. signal 31 shifts to low, but returns after a short time to low, where it stays for the rest of the period. The length of the high part of the pulse may be controlled by the differentiator used to establish it, and should correspond to the minimum pulse width that the output stage of the amplifier is able to realise without acceptable distortion. Such time may, e.g., be 100 ns, and in an embodiment where the switch frequency is 400 kHz, the high pulse is thus 4% of the time, and the duty cycle of the minimum duty cycle signal 32 is thus 4%. This represents the minimum pulse length realisable by the output stage.

Hence, by AND'ing the maximum duty cycle signal 32 to the pulse modulated signal 18, and OR'ing the minimum duty cycle signal 33 to the output of the AND'ing, it is ensured that there will be at least one level shift in each switch period, thereby supporting self-oscillation which requires the signal itself to oscillate, and thereby supporting stabilisation of the switch frequency, even at high level input signals, and at the same time it is ensured that no un-realisably short pulses are provided to the output stage for realising.

The error introduced by the non-linear limiting performed by the limit pattern logic 24 according to the present invention, is attenuated effectively because of the feedback and advantageous error attenuation of self-oscillating loops.

In a preferred embodiment, the pulses of the maximum and minimum duty cycle signals may be located at earlier time positions by means of a small delay in the feedback path from the square wave signal 31 to the input of the integrator in the periodic signal generator 22. Thereby the middle of the narrow pulses may be positioned at the triangle corners instead of starting at the corners, and thereby a more symmetric control signal is established.

In a preferred embodiment of the present invention, the periodic signal generator is further controlled by an external synchronization signal, which may, e.g., be fed to the comparator of the generator 22.

In a preferred embodiment of the present invention, the periodic signal generator may further be controlled by the input signal 3, in order to make the periodic signal generator depending on the input signal level. Thereby further possibilities of controlling the switch frequency on the basis of the input signal level is provided. Examples of such an input signal level controlled signal generator may, e.g., be found in the published, international patent application WO 2005/117253 A1 (in particular the parts about the level controlled generator), hereby incorporated by reference.

In a preferred embodiment of the present invention, the self-oscillating amplifier may comprise an additional feedback path from the output of the output filter 14 to the controller 11.

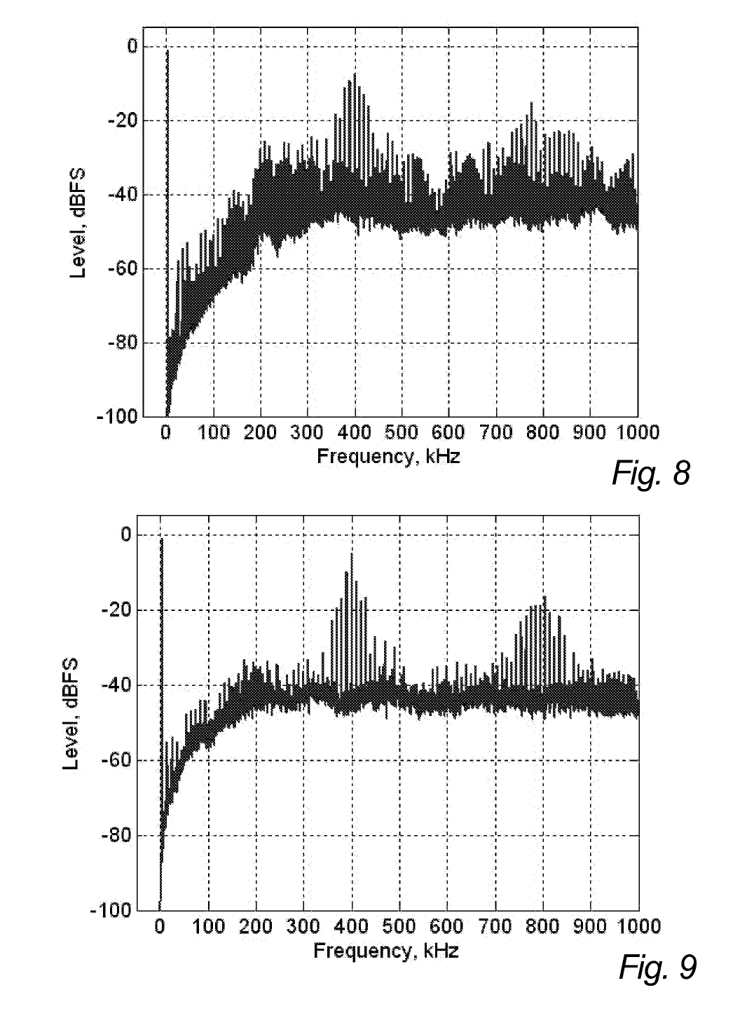

FIG. 6 illustrates an example of an output signal spectrum of a self-oscillating PWM modulator optimized for a switch frequency of approximately 400 kHz, but not comprising the improved synchronisation and PWM cycle constraint according to the present invention. The input signal used to generate the example is a −20 dBFS 5 kHz sinusoidal, i.e. a signal with a relatively small level. As seen from the curve, the spectrum looks nice and controlled, almost like a clean square-wave.

FIG. 7 illustrates a further example of an output spectrum of the same modulator as shown in FIG. 6, i.e. a modulator without the improved synchronization according to the present invention. In this example, the input signal level has been increased to −1 dBFS, i.e. a relatively high level. The signal is still a 5 kHz sinusoidal. The spectrum now looks quite complex. This is due to dropping frequency at increasing input levels, and FIG. 7 is thus an example of fluctuating switch frequency for high input signal levels.

FIG. 8 illustrates a further example of an output spectrum of the same modulator as shown in FIGS. 6 and 7, i.e. a modulator without the improved synchronization according to the present invention. The input signal is a high level signal of −1 dBFS as also used to generate FIG. 7. For the spectrum of FIG. 8, a small, periodic synchronization signal has, however, been added. Compared to the un-controlled spectrum of FIG. 7, this spectrum look a lot more behaved, but there is still a rather high level of switch components not related to the desired switch frequency.

FIG. 9 illustrates an example of an output spectrum of a modulator according to a preferred embodiment of the present invention, i.e. a modulator that comprises both a small, periodic synchronization signal, as well as a PWM cycle constrainer and limit pattern logic according to the present invention. The input signal is the same, relatively high level 5 kHz sinusoidal at −1 dBFS as used for generating the spectra of FIG. 6-8. As seen from the spectrum, the properties are significantly improved when compared to the spectra of FIG. 7 without any controlling, or FIG. 8 with a small sync-signal controlling. FIG. 9 shows that the present invention makes it possible to achieve a spectrum with the same properties as conventional, non-self-oscillating modulators, but with the advantages of self-oscillating modulators.

1.-56. (canceled)

57. Self-oscillating modulator arranged for establishing a pulse width modulated signal on the basis of an input signal, wherein said self-oscillating modulator comprises
a controller,
a modulator,
at least one feedback path, and
a PWM cycle constrainer,
wherein said PWM cycle constrainer comprises a PWM cycle constraint generator arranged for establishing at least one PWM cycle constraint representative signal, and limit pattern logic arranged for applying said at least one PWM cycle constraint representative signal to said pulse width modulated signal.

58. Self-oscillating modulator according to claim 57, wherein said at least one PWM cycle constraint representative signal is a pulse width modulated signal.

59. Self-oscillating modulator according to claim 57, wherein said at least one PWM cycle constraint representative signal comprises a maximum duty cycle representative signal and a minimum duty cycle representative signal.

60. Self-oscillating modulator according to claim 59,
wherein said maximum duty cycle signal comprises at least one pulse per switch period of said self-oscillating modulator, and wherein the duty cycle of said maximum duty cycle signal is in the range of 90% to 99% or corresponds to one full switch period of said self-oscillating modulator subtracted by an amount of time in the range of 50 ns to 200 ns, and
wherein said minimum duty cycle signal comprises at least one pulse per switch period of said self-oscillating modulator, and wherein the duty cycle of said minimum duty cycle signal is in the range of 1% to 10% or corresponds to an amount of time in the range of 50 ns to 200 ns.

61. Self-oscillating modulator according to claim 60,
wherein the low part of said pulse per switch period of said maximum duty cycle signal is located so that the middle in terms of time of said low part is located substantially at the shift between two switch periods, and
wherein the high part of said pulse per switch period of said minimum duty cycle signal is located so that the middle in terms of time of said high part is located substantially at the middle of each switch period.

62. Self-oscillating modulator according to claim 61, wherein said locating said pulses of said at least one PWM cycle constraint representative signal is controlled at least partly by a delay in a feedback path of said PWM cycle constraint generator.

63. Self-oscillating modulator according to claim 59, wherein said limit pattern logic applies said at least one PWM cycle constraint representative signal to said pulse width modulated signal by applying said maximum duty cycle signal to said pulse width modulated signal by means of an AND operation, and applying said minimum duty cycle signal to said pulse width modulated signal by means of an OR operation.

64. Self-oscillating modulator according to claim 57, wherein said PWM cycle constraint generator establishes said at least one PWM cycle constraint signal on the basis of a periodic signal in synchrony with the oscillation of said self-oscillating modulator, and wherein a synchronization signal is provided as a reference signal to said modulator of said self-oscillating modulator.

65. Self-oscillating modulator according to claim 64, wherein said synchronization signal comprises a representation of said periodic signal.

66. Self-oscillating modulator according to claim 64, wherein said periodic signal is established by means of a self-oscillating loop.

67. Self-oscillating modulator according to claim 64, wherein said periodic signal is variable, and is controlled at least partly on the basis of a level of said input signal of said self-oscillating modulator.

68. Self-oscillating modulator according to claim 57, wherein said controller comprises a loop filter arranged for at least partly controlling the oscillation of said self-oscillating modulator, wherein said controller comprises at least one integrator.

69. Self-oscillating modulator according to claim 57, wherein said self-oscillating modulator comprises a power output stage.

70. Self-oscillating modulator according to claim 57, wherein said at least one PWM cycle constraint representative signal is in synchronization with the switch frequency of said self-oscillating modulator.

71. Self-oscillating modulator according to claim 57, wherein said input signal is an audio signal.

72. Method of stabilising a switch frequency of a self-oscillating modulator establishing a pulse width modulated signal on the basis of a high level audio input signal, whereby a maximum duty cycle signal is applied to said pulse width modulated signal by means of an AND operation, and a minimum duty cycle signal is applied to said pulse width modulated signal by means of an OR operation, to ensure that said pulse width modulated signal comprises at least one pulse for each switch period, said pulse representing a duty cycle between a minimum duty cycle defined by said minimum duty cycle signal and a maximum duty cycle defined by said maximum duty cycle signal.

73. Method of stabilising the switch frequency of a Self-oscillating modulator according to claim 72, whereby said self-oscillating modulator comprises a self-oscillating modulator arranged for establishing a pulse width modulated signal on the basis of an input signal, wherein said self-oscillating modulator comprises
a controller,
a modulator,
at least one feedback path, and
a PWM cycle constrainer,
wherein said PWM cycle constrainer comprises a PWM cycle constraint generator arranged for establishing at least one PWM cycle constraint representative signal, and limit pattern logic arranged for applying said at least one PWM cycle constraint representative signal to said pulse width modulated signal.

74. Method of avoiding pulses narrower than a predetermined minimum pulse width or wider than a predetermined maximum pulse width in a self-oscillating modulator establishing a pulse width modulated signal on the basis of a high level audio input signal, whereby a maximum duty cycle signal is applied to said pulse width modulated signal by means of an AND operation, and a minimum duty cycle signal is applied to said pulse width modulated signal by means of an OR operation, to ensure that said pulse width modulated signal comprises at least one pulse for each switch period, said pulse representing a duty cycle between a minimum duty cycle defined by said minimum duty cycle signal and a maximum duty cycle defined by said maximum duty cycle signal.

75. Method of avoiding pulses narrower than a predetermined minimum pulse width or wider than a predetermined maximum pulse width in a Self-oscillating modulator according to claim 74, whereby said self-oscillating modulator comprises a self-oscillating modulator arranged for establishing a pulse width modulated signal on the basis of an input signal, wherein said self-oscillating modulator comprises
a controller,
a modulator,
at least one feedback path, and
a PWM cycle constrainer,
wherein said PWM cycle constrainer comprises a PWM cycle constraint generator arranged for establishing at least one PWM cycle constraint representative signal, and limit pattern logic arranged for applying said at least one PWM cycle constraint representative signal to said pulse width modulated signal.

76. Method of providing at least one PWM cycle constraint representative signal for use in a self-oscillating modulator, whereby said PWM cycle constraint representative signal is established by the steps of:
providing a periodic signal by means of a reference signal generator,
providing a square wave signal on the basis of, and in synchrony with, said periodic signal, and
providing said PWM cycle constraint representative signal on the basis of, and in synchrony with, said square wave signal.

77. Method of providing at least one PWM cycle constraint representative signal according to claim 76, whereby said reference signal generator comprises a self-oscillating loop with a hysteresis comparator having its reference input coupled to a synchronization signal source.

78. Method of providing at least one PWM cycle constraint representative signal according to claim 77, whereby said providing said PWM cycle constraint representative signal comprises providing a maximum duty cycle signal which for each period of said periodic signal comprises a low part that is wider than or equal to a predetermined minimum pulse width, and further providing a minimum duty cycle signal which for each period of said periodic signal comprises a high part that is wider than or equal to a predetermined minimum pulse width.

79. Method of providing at least one PWM cycle constraint representative signal according to claim 77, whereby said PWM cycle constraint representative signal is used in a self-oscillating modulator arranged for establishing a pulse width modulated signal on the basis of an audio input signal, wherein said self-oscillating modulator comprises
a controller,
a modulator,
at least one feedback path, and
a PWM cycle constrainer,
wherein said PWM cycle constrainer comprises a PWM cycle constraint generator arranged for establishing at least one PWM cycle constraint representative signal, and limit pattern logic arranged for applying said at least one PWM cycle constraint representative signal to said pulse width modulated signal.
